(19) United States
(12) Patent Application Publication
(10) Pub. No.: US 2012/0028075 A1
(43) Pub. Date: Feb. 2, 2012

(54) THIN FILM MANUFACTURING METHOD AND THIN-FILM ELEMENT

(76) Inventors: Masahiro YAGI, Kanagawa (JP); Eiichi Ohta, Kanagawa (JP); Yoshikazu Akiyama, Kanagawa (JP); Ryoh Tashiro, Kanagawa (JP); Osamu Machida, Kanagawa (JP)

(21) Appl. No.: 13/179,711

(22) Filed: Jul. 11, 2011

(30) Foreign Application Priority Data
Jul. 30, 2010 (JP) 2010-173007

(51) Int. Cl. C23C 16/52; B32B 9/00

(52) U.S. Cl. 428/702; 427/8

(57) ABSTRACT

A thin film manufacturing method includes placing a substrate in a raw material solution with which a thin film is formed on a first principal plane of the substrate; forming the thin film on the first principal plane of the substrate by applying light to a first principal plane side from a light source; measuring a distance from the first principal plane of the substrate to a liquid surface of the raw material solution by applying light from the light source; and adjusting a position of the substrate in a height direction on the basis of a measurement result obtained at the measuring.

### CROSS-REFERENCE TO RELATED APPLICATIONS

The present application claims priority to and incorporates by reference the entire contents of Japanese Patent Application No. 2010-173007 filed in Japan on Jul. 30, 2010.

### BACKGROUND OF THE INVENTION

1. Field of the Invention

The present invention relates to a thin film manufacturing method and a thin-film element.

2. Description of the Related Art

Conventionally, a chemical solution deposition (CSD) method has been known as a method of forming a thin film, such as a piezoelectric element. In the CSD method, a raw material solution is applied to and dried on a substrate so that a thin film is formed on a surface of the substrate. For example, Japanese Patent No. 3346214 discloses a method of forming a dielectric thin film by using a metal oxide precursor solution containing a metal oxide precursor and a pigment.

However, in the CSD method, a process of applying and drying a metal oxide precursor solution is extremely laborious and leads to increase in costs. Furthermore, there is a problem in that a thin film easily cracks during a drying process.

The present invention has been made in view of the above problem, and it is an object of the present invention to provide a thin film manufacturing method capable of manufacturing a thin film of stable quality at a low cost and to provide a thin-film element formed of the thin film manufactured by the thin film manufacturing method.

The above related art is for example also related to Japanese Patent No. 4108502.

### SUMMARY OF THE INVENTION

It is an object of the present invention to at least partially solve the problems in the conventional technology.

According to an aspect of the present invention, there is provided a thin film manufacturing method that includes placing a substrate in a raw material solution with which a thin film is formed on a first principal plane of the substrate; forming the thin film on the first principal plane of the substrate by applying light to a first principal plane side from a light source; measuring a distance from the first principal plane of the substrate to a liquid surface of the raw material solution by applying light from the light source; and adjusting a position of the substrate in a height direction on the basis of a measurement result obtained at the measuring.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a diagram explaining a thin film manufacturing method according to a first embodiment;

FIG. 2 is a diagram illustrating a thin-film pattern;

FIG. 3 is a diagram explaining a method of measuring a distance between a first principal plane of a substrate and a liquid surface of a metal oxide precursor solution (a thickness of a metal oxide precursor solution layer);

FIG. 4 is a diagram explaining irradiation positions of a laser beam;

FIG. 5 is a diagram illustrating a piezoelectric element, in which a thin film formed by the thin film manufacturing method according to the embodiment is used as an active layer;

FIG. 6 is a diagram explaining a first modification of the thin film manufacturing method according to the first embodiment;

FIG. 7 is a diagram illustrating a thin-film pattern formed on a first principal plane of an electrode layer;

FIG. 8 is a diagram explaining a fourth modification of the first embodiment; and

FIG. 9 is a diagram explaining a thin film manufacturing method according to a third embodiment.

### DETAILED DESCRIPTION OF THE PREFERRED EMBODIMENTS

Exemplary embodiments of a thin film manufacturing method and a thin-film element according to the present invention will be explained in detail below with reference to the accompanying drawings.

### First Embodiment

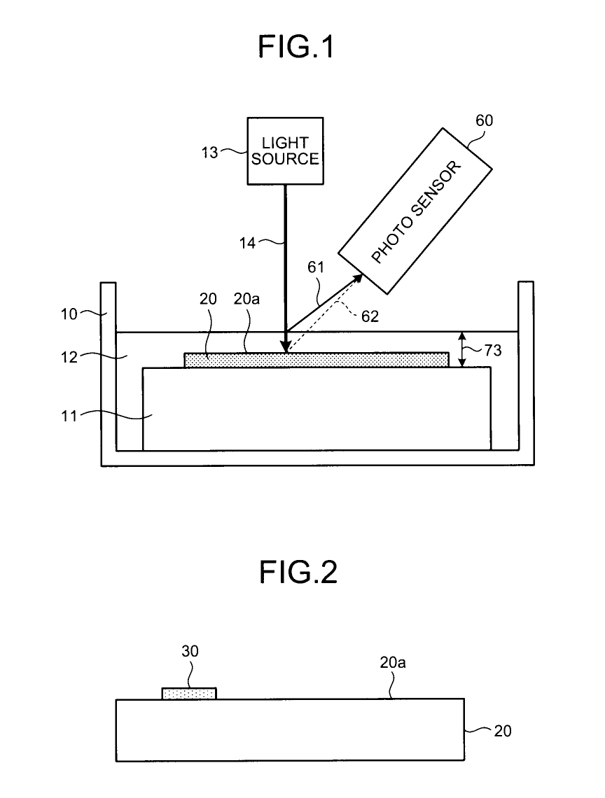

FIG. 1 is a diagram explaining a thin film manufacturing method according to a first embodiment. In the following embodiment, a thin film manufacturing method relating to a thin film used for a piezoelectric element will be described as an example.

As illustrated in FIG. 1, a holder 11 that has a mechanism capable of automatically adjusting a height of a reaction vessel 10 is set, and a substrate 20, on which a thin film is to be formed, is placed on the holder 11. The reaction vessel 10 is filled with a metal oxide precursor solution 12. A light source 13 and a photo sensor 60 are placed above the substrate 20, that is, on a first principal plane 20a side of the substrate 20. The light source 13 applies a laser beam 14 from above the metal oxide precursor solution 12. The photo sensor 60 receives diffusely reflected light 61, which is a part of light that has been diffusely reflected from a liquid surface of the metal oxide precursor solution 12, and diffusely reflected light 62, which is a part of light that has been diffusely reflected from a surface of the substrate. Then, a thickness 73 of a metal oxide precursor solution layer formed on the substrate 20 is calculated on the basis of a measurement principle to which generally-known triangulation is applied; information on the thickness is fed back to an apparatus (not illustrated) that controls drive of the holder 11; and a thin film is formed while the thickness 73 of the metal oxide precursor solution layer is maintained constant.

As a result, as illustrated in FIG. 2, a thin-film pattern 30 that is made of amorphous metal oxide or crystalline metal oxide, which is obtained from a metal oxide precursor, is formed, that is, a metal-oxide thin film of stable quality is formed, at a position corresponding to an irradiation position of the laser beam on the first principal plane 20a of the substrate 20 at a low cost. By using a laser source device equipped with a scanning function, it is possible to form the thin-film pattern 30 at a desired position on the first principal plane 20a of the substrate 20. As for light applied to the substrate 20, light with a wavelength appropriate for formation of a thin film is selected depending on the metal oxide precursor solution 12.

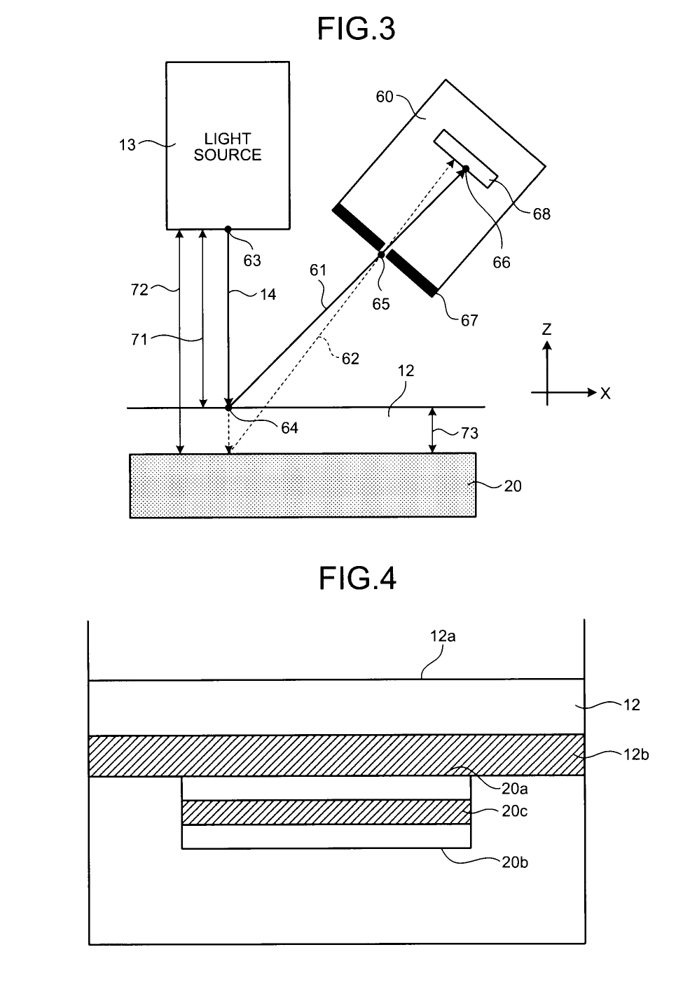

FIG. 3 is a diagram explaining the measurement principle, to which generally-known triangulation is applied and which is used in the thin film manufacturing method according to the first embodiment. According to the first embodiment, the light source 13, which is used for formation of a thin film, also emits a laser beam in order to calculate a distance between the first principal plane 20a of the substrate 20 and the liquid surface of the metal oxide precursor solution 12, i.e., the thickness 73 of the metal oxide precursor solution layer.

First, it will be explained below how to measure a distance 71 from the light source 13 to the liquid surface of the metal oxide precursor solution 12. In FIG. 3, the reference numeral 61 denotes the diffusely reflected light of a laser beam having been applied to and diffusely reflected from the liquid surface of the metal oxide precursor solution 12; the reference numeral 62 denotes the diffusely reflected light of a laser beam having been applied to and diffusely reflected from the surface of the substrate; a reference numeral 63 denotes a light-emitting point through which the laser beam is emitted by the light source 13; a reference numeral 64 denotes a measuring point on a measuring object (according to the embodiment, on the liquid surface of the metal oxide precursor solution 12); a reference numeral 65 denotes a slit pass-through at which the diffusely reflected light is incident on the photo sensor 60; a reference numeral 66 denotes a light-receiving point at which the diffusely-reflected light is incident on a light-receiving element; a reference numeral 67 denotes a slit arranged at a gate of the photo sensor 60; a reference numeral 68 denotes the light-receiving element of the photo sensor 60; the reference numeral 71 denotes a distance from the light-emitting point 63 to the surface of the metal oxide precursor solution 12; a reference numeral 72 denotes a distance from the light-emitting point 63 to the substrate 20; and the reference numeral 73 denotes the thickness of the metal oxide precursor solution layer. Orientations of the above units will be explained on the basis of XZ coordinates indicated in the figure.

The laser beam 14 emitted from the light-emitting point 63 is diffusely reflected in every direction at the measuring point 64 on the liquid surface of the metal oxide precursor solution 12. The reflected light 61, which is a part of the diffusely reflected light, passes through the slit pass-through 65 in the slit 67 of the photo sensor 60 and is irradiated on the light-receiving element 68, where the irradiated point is recognized as the light-receiving point 66. Positions of the units, such as the light source 13 and the photo sensor 60, are fixed, so that the positions of the light-emitting point 63 and the slit pass-through 65 are fixed. Accordingly, coordinates (X, Z) of the light-receiving point 66 on the light-receiving element 68 is measured. With use of the coordinates (X, Z), it is possible to calculate the distance 71 from the light-emitting point 63 to the liquid surface of the metal oxide precursor solution 12 on the basis of the measurement principle to which known triangulation is applied.

Second, the distance 72 from the light source 13 to the first principal plane 20a of the substrate 20 is measured in the same manner as the above-mentioned triangulation. Thereafter, the thickness 73 is calculated by subtracting the distance 71 between the light-emitting point 63 and the liquid surface of the metal oxide precursor solution 12 from the distance 72.

According to the first embodiment, a device that controls drive of the holder 11 adjusts a position of the substrate 20 in a height direction on the basis of a result of measurement, i.e., the calculated thickness 73 of the metal oxide precursor solution layer, so that the thickness 73 of the metal oxide precursor solution layer can be made uniform.

As an irradiation position of a laser beam from the light source 13, as illustrated in FIG. 4, following five positions are possible: on a liquid surface 12a of the metal oxide precursor solution 12; in an inside 12b of the metal oxide precursor solution 12; on the first principal plane 20a of the substrate 20; in an inside 20c of the substrate 20; and on a second principal plane 20b that is a back side of the first principal plane 20a of the substrate 20. By adjusting a focal point of the laser beam 14, light is applied to each irradiation position. The substrate 20 is arranged so that, when the irradiation position is located on or in the metal oxide precursor solution 12, the first principal plane 20a of the substrate 20 is located at a relatively shallow position in the metal oxide precursor solution 12 in such a manner that the irradiation position and a position at which a thin film is formed on the first principal plane 20a are not misaligned with each other. The irradiation positions and respective effects are shown in Table 1.

TABLE 1

| | | | | | a. | | | | | |
|---|---|---|---|---|---|---|---|---|---|---|
| | | | | | Formation | | | | | |
| | | | | | of | | c. | d. | | f. |
| | | | | | thin | | High | High- | e. | Simplicity |
| | | | | | film | b. | adhesiveness | precision/ | High | and ease |
| | | Behavior of | | Solution | with low | Less | between | high- | selectivity | of light |
| | Heated | light energy | | reaction | impurity | damage | substrate | resolution | of substrate | energy |
| Case | position | Solution | Substrate | pattern | concentration | of substrate | and film | patterning | material | equipment |
| A | On | Absorbed | — | Direct | ∘ | ∘ | x | ∘ | ∘ | x |
| | liquid | | | heating | | | | | | |
| | surface | | | | | | | | | |
| | of | | | | | | | | | |
| | solution | | | | | | | | | |
| B | In | Absorbed | — | Direct | ∘ | ∘ | x | ∘ | ∘ | x |
| | solution | | | heating | | | | | | |
| C | On | Transmitted | Absorbed | Indirect | x | x | ∘ | x | ∘ | ∘ |
| | interface | | | heating | | | | | | |
| | between | | | | | | | | | |
| | solution | | | | | | | | | |
| | and | | | | | | | | | |
| | substrate | | | | | | | | | |
| D | In | Transmitted | Absorbed | Indirect | x | x | ∘ | x | ∘ | ∘ |
| | substrate | | | heating | | | | | | |
| E | On back | Transmitted | Absorbed | Indirect | x | x | ∘ | x | ∘ | ∘ |
| | surface | | | heating | | | | | | |
| | of | | | | | | | | | |
| | substrate | | | | | | | | | |

In a case A, the irradiation position, i.e., a heated position, is located on the surface of the metal oxide precursor solution 12. In this case, several tens of percent of energy of light is absorbed by the metal oxide precursor solution 12, and the rest of the light energy reaches the substrate 20, where the light energy is absorbed or permeated. A reaction pattern of the solution is direct heating of a solution. In a case B, the heated position is located in the metal oxide precursor solution 12. In this case, light energy is absorbed by the metal oxide precursor solution 12. The solution reaction pattern is direct heating.

In a case C, the heated position is located on an interface between the metal oxide precursor solution 12 and the substrate 20, i.e., on the first principal plane 20a of the substrate 20. In a case D, the heated position is located in the inside 20c of the substrate 20. In a case E, the heated position is located on the second principal plane 20b of the substrate 20. In the cases C, D, and E, most light energy permeates the metal oxide precursor solution 12, and several percent of the light energy is absorbed by the substrate 20. The reaction pattern of each of the solutions in cases C, D, and E is indirect heating of the metal oxide precursor solution 12 due to heating of the substrate 20. In the case of direct heating, light with a wavelength of 400 nm or shorter is applied. In the case of indirect heating, light with a wavelength of 400 nm or longer is applied.

In terms of (a) formation of a thin film with low impurity concentration, the cases A and B, in which direct heating is applied, are excellent. In the cases A and B, the light energy can directly break carbon-oxygen bonding in the metal oxide precursor solution 12. Therefore, a carbon residue or soot is less likely to be generated. Consequently, it is possible to manufacture a high-quality thin film with a very low density of impurities. By contrast, in the cases C, D, and E, incomplete thermal decomposition is likely to occur in the metal oxide precursor solution 12 due to indirect heating. Therefore, there is a problem in that a carbon residue or soot is generated.

In terms of (b) damage of the substrate 20, the cases A and B are excellent. In the cases A and B, because the light energy can hardly reach the substrate 20, it is possible to suppress damage of the substrate 20. By contrast, in the cases C, D, and E, because the substrate 20 is heated, the substrate 20 may be thermally damaged.

In terms of (c) adhesiveness between the substrate and a film, the cases C, D, and E are excellent. In the cases C, D, and E, phase transition occurs in a solution near the first principal plane 20a of the substrate 20, so that the adhesiveness between the substrate 20 and a thin film can be improved. By contrast, in the cases A and B, phase transition occurs at the surface 12a of the metal oxide precursor solution 12 or in the inside 12b of the metal oxide precursor solution 12, so that the adhesiveness between the substrate 20 and a thin film becomes relatively low.

In terms of (d) high-precision/high-resolution patterning, the cases A and B are excellent. In the cases A and B, it is possible to perform patterning with high precision and at high resolution based on a spot diameter of the light energy. By contrast, in the cases C, D, and E, a heated area may become larger than the spot diameter of the light energy because of thermal characteristics of the substrate 20; therefore, these cases are inferior to the cases A and B.

In terms of (e) selectivity of a substrate material, all of the cases are excellent. As the substrate 20, a silicon substrate may be used. In terms of (f) a light source, in the cases A and B, because light with a short wavelength of 400 nm or shorter is used as irradiation light, it is necessary to use a device, such as an ultraviolet (UV) laser, that is expensive and is difficult to handle. By contrast, in the cases C, D, and E, because light with a long wavelength of 400 nm or longer is used as irradiation light, it is possible to use a device, such as a CO₂ laser, that is relatively inexpensive and has a utilization track record in processing purposes.

Processes other than a process of immersing the substrate in the metal oxide precursor solution are the same as those of a thin-film forming process performed in a conventional sol-gel method. Also, the metal oxide precursor solution is similar to a metal oxide precursor solution that is applied to a substrate in the sol-gel method.

When the substrate 20 is taken out of the metal oxide precursor solution 12 after a thin film is formed in the metal oxide precursor solution 12, ultrasonic cleaning or rinse cleaning with a solvent is performed on the substrate 20. Regarding the solvent, it is preferable to use a material that relatively easily volatilizes and that has low water content in liquid. More specifically, acetone, ethanol, or isopropyl alcohol (IPA) may be used as the solvent. Accordingly, it is possible to prevent metal alkoxide contained in the metal oxide precursor solution 12 from remaining on the substrate to become residues.

Furthermore, after the above-mentioned cleaning is performed, heat treatment is appropriately performed depending on a state of the formed thin film (mainly depending on a difference in a crystal form). When the thin film is a crystal, a heating process is performed, for a purpose of drying, for about 3 minutes to 10 minutes at a temperature that does not influence a crystal form. A heating temperature is in a range of about, for example, 100° C. to 150° C. An atmosphere is generally air; however, an appropriate atmosphere is arbitrarily used depending on a property of the thin film. For example, when the thin film is deliquescent, an inert gas atmosphere with a small amount of residual water content is used. When the thin film is non-crystalline, some materials, such as a piezoelectric material, do not realize functions unless they are crystallized. For these materials, a heating process for crystallization is performed. A heating temperature and heating duration depend on the materials. In the case of lead zirconate titanate (PZT), the heating temperature is in a range of approximately 600° C. to 800° C. and the heating duration is 1 minute to 10 minutes.

More specifically, as the metal oxide precursor, a material that can form a metal-oxide thin film, i.e., a material that can form amorphous metal oxide or crystalline metal oxide, may be used. Examples of such a material include a metal complex, such as a metal alkoxide, a β-diketonate complex, or a metal chelate, and include a metal carboxylate. As a solvent, an ethanol organic solvent may be used.

Examples of the metal alkoxide include alkoxide of any metals, such as Si, Ge, Ga, As, Sb, Bi, V, Na, Ba, Sr, Ca, La, Ti, Ta, Zr, Cu, Fe, W, Co, Mg, Zn, Ni, Nb, Pb, Li, K, Sn, Al, or Sm. Any metal alkoxides containing an alkoxy group, such as OCH₃, OC₂H₅, OC₃H₇, OC₄H₉, or OC₂H₄OCH₃, can also be used.

Examples of the β-diketonate complex include a metal with, for example, acetylacetone, benzoylacetone, benzoyl trifluoroacetone, benzoyl difluoroacetone, or benzoyl fluoroacetone.

Examples of the metal carboxylate include barium acetate, copper(II) acetate, lithium acetate, magnesium acetate, lead acetate, barium oxalate, calcium oxalate, copper(II) oxalate, magnesium oxalate, and tin(II) oxalate. Examples of the solvent include an alcohol organic solvent. Concentration of a solution is preferably 0.1 mol/l to 1 mol/l, and more preferably, 0.3 mol/l to 0.7 mol/l. The upper limit of the concentration is determined from a viewpoint of stability of a liquid. The lower limit of the concentration is determined on the basis of a deposition rate of the thin film.

According to the embodiment, the laser beam 14 is applied either to the metal oxide precursor solution 12 or to the substrate 20 while the substrate 20 is immersed in the metal oxide precursor solution 12, so that a thin film is formed only on a portion irradiated with the laser beam 14. Therefore, it is possible to omit a process of attaching and drying a metal oxide precursor solution and a process of dry etching or wet etching for removing metal oxide precursor, which has been needed in the conventional sol-gel method and which are generally very expensive. Because these processes are not needed in the thin film manufacturing method according the embodiment, it is possible to greatly reduce costs.

Furthermore, because a thin-film forming reaction occurs in the metal oxide precursor solution 12, supply of the metal oxide precursor solution 12 is maintained during the thin-film forming reaction, so that a thin film is less likely to crack.

Moreover, according to the embodiment, the light source 13, which is used for formation of a thin film, also emits the laser beam 14 in order to calculate a distance between the first principal plane 20a and the liquid surface of the metal oxide precursor solution 12, i.e., the thickness 73 of the metal oxide precursor solution layer, and the position of the substrate 20 in the height direction is adjusted on the basis of the thickness 73 of the metal oxide precursor solution layer so that the thickness 73 can be maintained constant. Therefore, it is possible to manufacture a thin film of stable quality with a simple structure and at a low cost.

A thin film formed by the thin film manufacturing method according to the embodiment can be used for, for example, an ultrasonic piezoelectric element, a nonvolatile memory element, or an actuator element. The actuator element may be used for, for example, a recording head of an ink-jet printer.

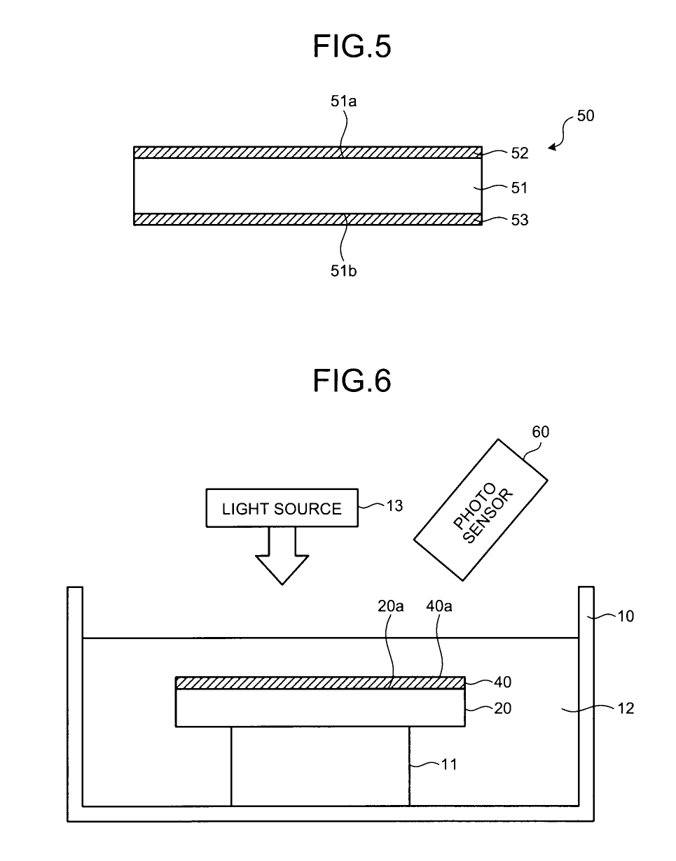

FIG. 5 is a diagram illustrating a piezoelectric element 50, in which a thin film formed by the thin film manufacturing method according to the embodiment is used as an active layer. The piezoelectric element 50 includes a piezoelectric film 51; a first electrode 52 that is formed on a first principal plane 51a of the piezoelectric film 51; and a second electrode 53 that is formed on a second principal plane 51b of the piezoelectric film 51. The piezoelectric film 51 is a thin film formed by the thin film manufacturing method. The first electrode 52 and the second electrode 53 are structured with a conductive material having high optical permeability, such as lanthanum nickel oxide or strontium ruthenium oxide. The first electrode 52 and the second electrode 53 may be formed by using, for example, a sputtering method or a vacuum deposition method.

FIG. 6 is a diagram explaining a first modification of the thin film manufacturing method according to the first embodiment. In the thin film manufacturing method according to the first modification, the substrate 20, in which an electrode layer 40 is already formed on the first principal plane 20a, is used. The electrode layer 40 is structured with a conductive material and formed by using a sputtering method or the like. The electrode layer 40 may be deposited on the substrate 20 in a patterned manner.

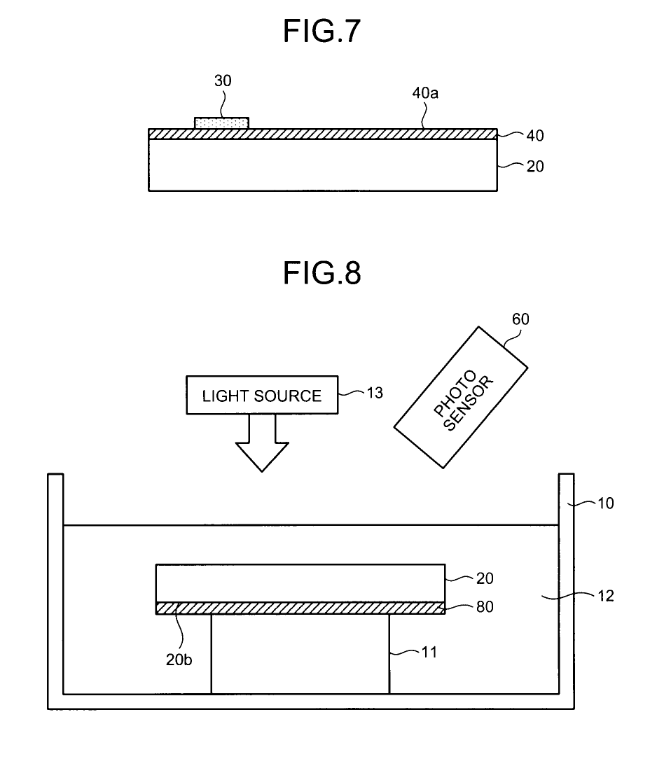

The substrate 20, on which the electrode layer 40 is formed, is immersed in the metal oxide precursor solution 12, so that the thin-film pattern 30 is formed on a first principal plane 40a of the electrode layer 40 as illustrated in FIG. 7. Processes, such as a process using the method of measuring the thickness 73 of the metal oxide precursor solution layer, other than the above process are the same as those of the thin film manufacturing method according to the first embodiment. Furthermore, the effects of irradiation at each irradiation position are the same as those obtained without depositing the electrode layer 40 as explained with reference to Table 1. In the case C, a laser beam is applied to the first principal plane 40a of the electrode layer 40 instead of the first principal plane 20a.

As a second modification, it is possible to use the substrate 20 in which a light-absorbing layer, instead of the electrode layer 40, that absorbs the laser beam 14, which has a specific wavelength and which is applied from the light source 13, is formed on the first principal plane 20a of the substrate 20. The light-absorbing layer may be deposited on the substrate 20 in a patterned manner. As the light-absorbing layer, metal oxide, nitride, or carbide, such as SiO₂, SiN, TiO₂, or SiC, may be used depending on the wavelength of the laser beam 14.

The substrate 20, on which the light-absorbing layer is formed, is immersed in the metal oxide precursor solution 12, so that a thin-film pattern is formed on a first principal plane of the light-absorbing layer. Processes other than the above process are the same as those performed when a thin film is formed on the first principal plane 40a of the electrode layer 40. By arranging the light-absorbing layer, it is possible to improve optical absorptance of the substrate 20, enabling to absorb more energy.

As a third modification, the electrode layer 40 explained in the first modification is configured to also function as a light-absorbing layer. The electrode layer 40 that also functions as the light-absorbing layer may be formed by using a material that can function as an electrode, e.g., a material for an oxide electrode, such as LaNiO₃, SrRuO₃, or ITO. Furthermore, when a conductive film is formed with a lanthanum nickel oxide solution by using, for example, the CSD method, a conductive film that also functions as a light-absorbing layer can be formed by mixing a material that can improve optical absorptance, such as a pigment, with the metal oxide precursor solution 12.

As a fourth modification, as illustrated in FIG. 8, a light reflection layer 80 is formed on the second principal plane 20b that is the back side of the substrate 20, and the substrate 20 is immersed in the metal oxide precursor solution 12. Accordingly, light reflected from the light reflection layer 80 re-enters the substrate 20, so that a thin-film forming reaction can be accelerated. As the light reflection layer 80, metal, such as Au, Ag, Al, or Pt, may be used depending on a wavelength of a laser beam to be used.

According to the first embodiment, formation of a thin film that is used as a piezoelectric element has been explained as an example. However, types of a thin film to be formed are not limited to that of the first embodiment. Various types of thin films can be formed by the above thin film manufacturing method. When manufacturing a thin film, it is sufficient to immerse a substrate in a raw material solution that is used as a raw material of the thin film. The raw material solution and a material of the substrate are not limited to those described in the first embodiment.

Examples of the thin film manufactured by using the thin film manufacturing method according to the first embodiment include a thin film that is translucent and has an electro-optical effect. The thin film that is translucent and has the electro-optical effect may be used as an optical waveguide, an optical switch, a spatial modulation element, an image memory, or the like.

In the above first embodiment, the cases A to E, in each of which a laser beam is applied to a different irradiation position in a different irradiation direction, are explained. Meanwhile, it is possible to evaluate each case by calculating a total evaluation score of all items (a to f) on the assumption that a score of 1 is given to a circle, a score of 0.5 is given to a triangle, and a score of 0 is given to a symbol X in Table 1. Furthermore, a total score of all items may be calculated by giving a weight to an important item, and each of the cases may be evaluated on the basis of the total score thus calculated.

### Second Embodiment

In a second embodiment, a structure is made such that, in addition to the structure of the first embodiment, output power of the light source 13 is adjusted on the basis of the distance between the first principal plane 20a of the substrate 20 and the liquid surface of the metal oxide precursor solution 12 (the thickness 73 of the metal oxide precursor solution layer).

In the second embodiment, the thickness 73 of the metal oxide precursor solution layer on the substrate 20 is calculated with the same structure and in the same manner as those of the first embodiment. Then, information on the thickness 73 of the metal oxide precursor solution layer is fed back to a control device (not illustrated) that controls an output of the laser beam 14 from the light source 13, and the output power of the laser beam 14 is adjusted depending on the thickness 73 of the metal oxide precursor solution layer so that a uniform thin film can be formed.

Regarding a relation between the thickness 73 of the metal oxide precursor solution layer and output power of a laser beam, experimental data is measured in advance. For example, properties of thin films are measured under a condition in which thin films are formed by changing the thicknesses 73 of the metal oxide precursor solution layer from 0.1 μm to 5 μm with a pitch of 0.1 μm and by changing the output power of the laser beam 14 applied to the films from 1 percent to 100 percent with a pitch of 1 percent.

In general, when the output power of the laser beam is too large, a thin film cracks or comes off. On the other hand, when the output power of the laser beam is too small, a solvent medium of the metal oxide precursor solution 12 is not completely dried or crystallizability of a film is reduced. As a means for measuring properties of a film, an X-ray diffraction (XRD) apparatus or a Fourier transform infrared spectroscopy (FTIR) apparatus is generally used. By selecting an appropriate output power of a laser beam from the above experimental data depending on the thickness of a film and emitting the laser beam with the appropriate output power, it is possible to form a uniform and highly-reliable film.

### Third Embodiment

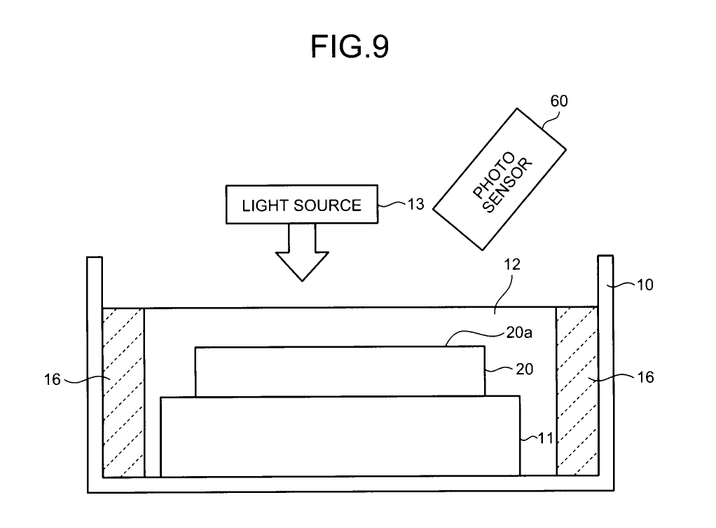

In a third embodiment, as illustrated in FIG. 9, a damper 16 is arranged on an inner wall of the reaction vessel 10. The damper 16 is arranged on the whole surface of the inner wall of the reaction vessel 10. Examples of the damper 16 include a porous member, such as a sponge. From the viewpoint of dispersing a shockwave, a material having viscoelastic characteristics equivalent to that of the metal oxide precursor solution 12 may be used as the damper 16. More specifically, a resin bag containing a solution having viscosity equal to or greater than that of the metal oxide precursor solution 12 may be used as the damper 16. The viscosity of the metal oxide precursor solution 12 is about 1-30 mPa·sec.

When waves occur on the liquid surface of the metal oxide precursor solution 12, a laser light emitted from the light source 13 is irregularly reflected from the liquid surface, so that the shape of an irradiation spot may be distorted. Therefore, it becomes difficult to perform patterning with high precision.

Furthermore, due to occurrence of the waves, the height of the metal oxide precursor solution 12 locally changes. Therefore, a depth of light permeability of the light energy, a focal point of light and the like may change, so that it becomes difficult to efficiently transmit the energy to a targeted region. Moreover, a surface area of the metal oxide precursor solution 12 increases due to occurrence of the waves, so that an evaporation rate of the metal oxide precursor solution 12 increases. Therefore, physical property (particularly, viscosity) of the metal oxide precursor solution 12 changes, changing film formation property.

To cope with the above situation, if the damper 16 is arranged on the wall of the reaction vessel 10 as described in the second embodiment makes, it becomes possible to suppress the occurrence of the waves, enabling to manufacture a high-quality thin film.

Processes other than the above processes in the thin film manufacturing method according to the third embodiment are the same as those of the thin film manufacturing methods according to the other embodiments.

According to the third embodiment, the thickness 73 of the metal oxide precursor solution layer on the substrate 20 is calculated with the same structure and in the same manner as those of the first embodiment. Furthermore, according to the third embodiment, similarly to the first embodiment, the position of the substrate 20 in the height direction is adjusted on the basis of the calculated thickness 73 of the metal oxide precursor solution layer. Moreover, according to the third embodiment, similarly to the second embodiment, an output power of the laser beam 14 emitted from the light source 13 is adjusted depending on the thickness 73 of the metal oxide precursor solution layer.

As another example, the structure may be as follows: a hard material, such as aluminum, is used as a material of the damper 16; a height and a phase of a wave that occurs on the liquid surface of the metal oxide precursor solution 12 are detected; and the damper 16 is driven with an opposite phase to a phase of the wave on the basis of the height and the phase of the wave so that the wave can be reduced.

According to one aspect of the present invention, it is possible to manufacture a thin film of stable quality at a low cost.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A thin film manufacturing method comprising:
placing a substrate in a raw material solution with which a thin film is formed on a first principal plane of the substrate;
forming the thin film on the first principal plane of the substrate by applying light to a first principal plane side from a light source;
measuring a distance from the first principal plane of the substrate to a liquid surface of the raw material solution by applying light from the light source; and
adjusting a position of the substrate in a height direction on the basis of a measurement result obtained at the measuring.

2. The thin film manufacturing method according to claim 1, wherein
the raw material solution is a metal oxide precursor solution, and
the thin film is a metal-oxide thin film.

3. The thin film manufacturing method according to claim 1, wherein
the forming includes applying light with a wavelength of 400 nm or shorter from the first principal plane side to the liquid surface of the raw material solution that is set as an irradiation position.

4. The thin film manufacturing method according to claim 1, wherein
the forming includes applying light with a wavelength of 400 nm or shorter from the first principal plane side to a position located inside the raw material solution as an irradiation position.

5. The thin film manufacturing method according to claim 1, wherein
the forming includes applying light with a wavelength of 400 nm or longer from the first principal plane side to the first principal plane of the substrate as an irradiation position.

6. The thin film manufacturing method according to claim 1, wherein
the forming includes applying light with a wavelength of 400 nm or longer from the first principal plane side to a position located inside the substrate as an irradiation position.

7. The thin film manufacturing method according to claim 1, wherein
the forming includes applying light with a wavelength of 400 nm or longer from the first principal plane side to a second principal plane that is a back side of the first principal plane of the substrate as an irradiation position located.

8. The thin film manufacturing method according to claim 1, further comprising:
a damper for reducing a wave that occurs on the raw material solution, the damper being arranged on an inner wall of a reaction vessel that is filled with a reaction solution.

9. A thin-film element that is formed of the thin film manufactured by the thin film manufacturing method according to claim 1.

10. A thin film manufacturing method comprising:
placing a substrate in a raw material solution with which a thin film is formed on a first principal plane of the substrate;
forming the thin film on the first principal plane of the substrate by applying light to a first principal plane side from a light source;
measuring a distance from the first principal plane of the substrate to a liquid surface of the raw material solution; and
adjusting an output power of light emitted from the light source on the basis of a measurement result obtained at the measuring.

11. The thin film manufacturing method according to claim 10, wherein
the raw material solution is a metal oxide precursor solution, and
the thin film is a metal-oxide thin film.

12. The thin film manufacturing method according to claim 10, wherein
the forming includes applying light with a wavelength of 400 nm or shorter from the first principal plane side to the liquid surface of the raw material solution that is set as an irradiation position.

13. The thin film manufacturing method according to claim 10, wherein
the forming includes applying light with a wavelength of 400 nm or shorter from the first principal plane side to a position located inside the raw material solution as an irradiation position.

14. The thin film manufacturing method according to claim 10, wherein
the forming includes applying light with a wavelength of 400 nm or longer from the first principal plane side to the first principal plane of the substrate as an irradiation position.

15. The thin film manufacturing method according to claim 10, wherein
the forming includes applying light with a wavelength of 400 nm or longer from the first principal plane side to a position located inside the substrate as an irradiation position.

16. The thin film manufacturing method according to claim 10, wherein
the forming includes applying light with a wavelength of 400 nm or longer from the first principal plane side to a second principal plane that is a back side of the first principal plane of the substrate as an irradiation position located.

17. The thin film manufacturing method according to claim 10, further comprising:
a damper for reducing a wave that occurs on the raw material solution, the damper being arranged on an inner wall of a reaction vessel that is filled with a reaction solution.

18. A thin-film element that is formed of the thin film manufactured by the thin film manufacturing method according to claim 10.
